(19) United States
(12) Patent Application Publication
(10) Pub. No.: US 2011/0039112 A1
(43) Pub. Date: Feb. 17, 2011

(54) OPTICAL COMPONENT USING COMPOSITE SUBSTRATE AND PROCESS FOR PRODUCING SAME

(75) Inventors: Taro Itatani, Ibaraki (JP); Hiroyuki Ishii, Ibaraki (JP); Hidetoshi Fujino, Ibaraki (JP); Hiroshi Hiroshima, Ibaraki (JP); Yuichi Kurashima, Yamanashi (JP); Iwao Miyamoto, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignees: National Institute of Advanced Indust Sci & Tech, Tokyo (JP); Tokyo University of Sci Edu Found Admin Org, Tokyo (JP)

(21) Appl. No.: 12/865,582

(22) PCT Filed: Jan. 29, 2009
(86) PCT No.: PCT/JP09/51921

§ 371 Date: Oct. 29, 2010

(30) Foreign Application Priority Data
Jan. 30, 2008 (JP) 2008-018777

(51) Int. Cl. B32B 9/04; C23C 14/34; B32B 17/06; B32B 15/04; B32B 38/00

(52) U.S. Cl. 428/426; 428/446; 204/192.1; 204/192.11; 428/457; 156/242

(57) ABSTRACT

A resin composition (2) such as a photo-curable resin composition or a heat curable or thermosetting resin composition is placed on an optical substrate (1). A printing pressure is applied to the side of the resin composition (2) of the optical substrate (1) with the resin composition (2) by means of an extra-flat pressing plate having a flatter plane than the optical substrate (1). The resin composition is cured by utilizing light or a temperature change to form a composite substrate. A thin film (4) such as a functional inorganic optical film, a dielectric multilayered optical thin film, or an optical functional metallic film is stacked on the composite substrate, for example, by low-temperature sputtering or ion beam sputtering to form an optical component such as a reflection mirror, a beam splitter, a band-pass filter, a band-stop filter, and an edge filter.

### TECHNICAL FIELD

The present invention relates to a process for producing an optical component, which can obtain an optical component having good characteristics even if using a not highly polished optical substrate, and an optical component produced by the production process.

### BACKGROUND ART

Currently, in the production of an optical thin film, glass of various compositions is usually used as a substrate for an optical thin film substrate, which is a raw material of the optical thin film, and the substrate has a highly polished surface. The substrate polishing requires a time based on repeated polishing treatments, expensive devices and the management thereof, and a huge amount of polishing techniques.

When a functional inorganic optical film stacked on a substrate surface based on the polishing of the substrate is produced, the functional inorganic optical film has a shape reflecting the substrate surface, and there has been known that the substrate surface significantly influences the accuracy and positional dependence of an optical thin film and an optical component using the optical thin film due to, for example, the degree of irregularities (surface roughness) and a distribution of undulation in the substrate. Thus, the substrate polishing is strongly required to reduce the surface roughness, the distribution of undulation, and so on.

Until now, although an extremely flat substrate has been obtained by a highly accurate polishing technique, recesses as polishing marks are locally provided on the surface of the substrate due to abrasive particles in the process of the polishing, and the recess portion causes increase in roughness. In the local position, the poor surface state causes reduction in performances of an optical thin film and an optical component using the optical thin film.

In the optical thin film, depending on the intended use, a metal thin film or a dielectric film uses a layer structure such as a single layer, a composite layer, and multiple layers based on the film design depending on the use. With regard to these stacking structures, a large number of production processes and devices have been known.

The recent optical component is required to have very high quality and accurate characteristics. Accompanying this, the substrate is required to improve the flatness, and an optical thin film with a smaller loss is required. For example, in a highly reflection mirror, in order to increase the reflectance of the mirror to limitlessly close to 100%, not an optical functional metallic film but a dielectric multilayered optical thin film is used, and the stacking device thereof is variously considered.

On the other hand, as a process for forming a micro-configuration, a nanoimprinting method has been known in which after a mold having a micro-configuration applies a printing pressure to a resin applied onto a substrate, curing or thermoplastic deformation is performed thereto, and the mold is separated from the resin, whereby the micro-configuration of the resin is provided on the substrate.

Patent Document 1 (Japanese Patent Laid-Open Publication No. 11-016491) discloses, in the production of a plasma display panel, a method for forming thick film pattern formation method which can reduce defects in a barrier layer, an electrode, and a dielectric layer and form these components respectively to be flat. A. material for forming thick film pattern containing an inorganic constituent having at least glass frit and a binder resin is applied or printed onto the entire surface of a substrate or onto the substrate in a patterned manner, and thereafter, a planarization treatment is performed thereto. In the planarization treatment, a barrier layer, an electrode, and a dielectric layer are pressed using a press roll or a press platen through or not through a peelable film.

Further, Patent Document 2 (Japanese Patent Laid-Open Publication No. 10-335837) discloses a process for producing a multilayer printed wiring board which can realize the planarization of the surface of an interlayer resin insulating layer even if surface irregularities exist in an inner-layer conductor circuit. This production process is characterized by, in the production of the multilayer printed wiring board, applying an uncured interlayer resin insulating agent onto a conductor circuit of a substrate to form an interlayer resin insulating layer, applying hot press to the interlayer resin insulating layer to planarize the surface of the interlayer resin insulating layer, and forming a conductor circuit on the planarized interlayer resin insulating layer.

Furthermore, Patent Document 3 (Japanese Patent Laid-Open Publication No. 10-319365) discloses a process for producing with high yield a liquid crystal element free from display defects. A transparent electrode is formed on a surface of a glass substrate, and a passivation film is formed so as to cover the transparent electrode. Thereafter, the surface of the passivation film is pressed with a pressing force of 40 kg/cm² by using a pressing member with a surface roughness of not more than 100 Å so that the surface is planarized.

Furthermore, Patent Document 4 (Japanese Patent Laid-Open Publication No. 8-152509) discloses a production process which, in the fabrication of a color filter through a printing method, can realize a simple planarization treatment of a substrate surface formed with a colored ink layer. In the production process, a patterned colored ink layer formed on a substrate through the printing method is provided, and before the colored ink layer dries, a coated roll 3 obtained by winding a release film 5 around a rubber roll 4 applies pressure to the colored ink layer, whereby the surface of the colored ink layer is pressed to be subjected to a planarization treatment.

However, this invention is different from the Patent Documents 1 to 4 in terms of providing a process for producing an optical component using a composite substrate having an extra-flat surface. Further, it is clear that this invention is different from the Patent Documents 1 to 4 in that a thin film is stacked on the composite substrate to form an optical component.

In view of the above, an object of the present invention is to provide a process for producing an optical component using a composite substrate, which is obtained by producing an extra-flat surface of a resin composition on a substrate regardless the presence of a high level of polishing of the substrate surface and stacking an optical thin film on the extra-flat surface, and the optical component.

### DISCLOSURE OF THE INVENTION

The present invention provides a process for producing an optical component using a composite substrate having an extra-flat surface. More specifically, a resin composition is placed on an optical substrate, the resin composition side of the optical substrate with the resin composition is subjected to application of a printing pressure by using an extra-flat pressing plate having an extremely flatter plane than the optical substrate, and the resin composition is cured to form a composite substrate. A thin film is then stacked on the composite substrate to form an optical component.

Especially, when a photo-curable resin composition is used as the resin composition, the photo-curable resin composition is placed on an optical substrate, the resin composition side of the optical substrate with the photo-curable resin composition is subjected to application of a printing pressure by using an extra-flat pressing plate having an extremely flatter plane than the optical substrate, and the photo-curable resin composition is subjected to light irradiation to be cured, and, thus, to form a composite substrate. A thin film is then stacked on the composite substrate to form an optical component.

Meanwhile, when a thermosetting or thermoplastic resin composition is used as the resin composition, the thermosetting or thermoplastic resin composition is placed on an optical substrate, the resin composition side of the optical substrate with the thermosetting or thermoplastic resin composition is subjected to application of a printing pressure by an extra-flat pressing plate having an extremely flatter plane than the optical substrate, and the thermosetting or thermoplastic resin composition is cured by a temperature change to form a composite substrate. A thin film is then stacked on the composite substrate to form an optical component.

For example, when the extra-flat pressing plate having an extremely flat plane is a semiconductor substrate material having a flat plane whose surface roughness is not more than 0.3 nm in terms of a root-mean-square average roughness (RMS), a resin surface of the composite substrate to be formed can have the surface roughness of not more than 0.3 nm in terms of the root-mean-square average roughness (RMS).

Likewise, when the extra-flat pressing plate having an extremely flat plane is a silicon substrate material having a flat plane whose surface roughness is not more than 0.3 nm in terms of the root-mean-square average roughness (RMS), a resin surface of the composite substrate to be formed can have the surface roughness of not more than 0.3 nm in terms of the root-mean-square average roughness (RMS).

Likewise, when the extra-flat pressing plate having an extremely flat plane is a highly accurate glass substrate material having a flat plane whose surface roughness is not more than 0.3 nm in terms of the root-mean-square average roughness (RMS), a resin surface of the composite substrate to be formed can have the surface roughness of not more than 0.3 nm in terms of the root-mean-square average roughness (RMS).

Likewise, when the extra-flat pressing plate having an extremely flat plane is a highly accurate low-thermal expansion glass substrate material having a flat plane whose surface roughness is not more than 0.3 nm in terms of the root-mean-square average roughness (RMS), a resin surface of the composite substrate to be formed can have the surface roughness of not more than 0.3 nm in terms of the root-mean-square average roughness (RMS).

When the thin film is a functional inorganic optical film, a reflection mirror can be formed by stacking the functional inorganic optical film.

Likewise, when the thin film is the functional inorganic optical film, a beam splitter can be formed by stacking the functional inorganic optical film.

Likewise, when the thin film is the functional inorganic optical film, a band-pass filter can be formed by stacking the functional inorganic optical film.

Likewise, when the thin film is the functional inorganic optical film, a band-stop filter can be formed by stacking the functional inorganic optical film.

Likewise, when the thin film is the functional inorganic optical film, an edge filter can be formed by stacking the functional inorganic optical film.

Likewise, when the thin film is the functional inorganic optical film, the thin film can be stacked by low temperature sputtering.

Likewise, when the functional inorganic optical film is used in the thin film, the thin film can be stacked by ion beam sputtering.

The thin film can be configured by using a dielectric multilayered optical thin film.

Likewise, the thin film can be configured by using an optical functional metallic film.

Further, the thin film can be configured by using the dielectric multilayered optical thin film or the optical functional metallic film. Namely, a stacked film of the thin film is a composite film comprising the dielectric multilayered optical thin film and the optical functional metallic film.

According to the above production process, an optical component using a stacked film can be produced.

In order to produce an optical component with a stacked thin film, in the prior art, many processes had had to be run in order to polish an optical substrate. Thus, the cost burden was high, and a huge amount of polishing techniques had had to be maintained. However, the present invention realizes the simplification of the polishing process of the optical substrate. Further, it is possible to terminate production within a relatively short time from the production of an optical substrate to the production of an optical component while maintaining high accuracy.

Further, there has been generally known that as the size of the optical substrate is increased, the polishing of the optical substrate becomes very difficult. In the prior art, polishing had had to be applied to each optical substrate, however, in the present invention, one extra-flat pressing plate may be produced relative to the required size of a substrate, whereby the required number of times of polishing can be reduced.

### BRIEF DESCRIPTION OF THE DRAWINGS

FIG. 1 is a cross-sectional view for each process of a composite substrate and a highly reflection mirror of the present invention.

FIG. 2 is a view showing a reflection and transmission spectrum of the highly reflection mirror produced in an Embodiment 1.

FIG. 3 is a view showing a reflection and transmission spectrum of a beam splitter produced in an Embodiment 3.

### BEST MODE FOR CARRYING OUT THE INVENTION

Hereinafter, the present invention will be described in detail using the following embodiments. Since there is a wide variety of kinds and sizes of samples, resins and the processing devices, and laminate designs, the invention is not limited to only the following embodiments.

### Embodiment 1

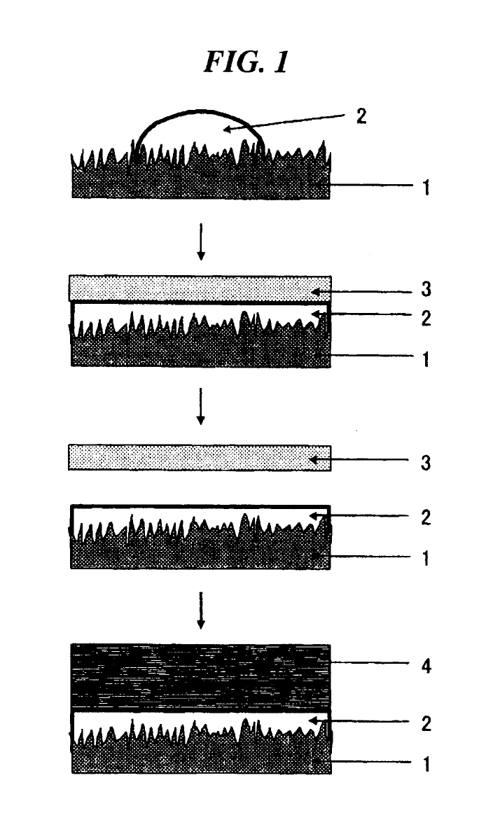

As shown in FIG. 1, an appropriate amount of an acrylic liquid photo-curable resin composition 2 (from Toyo Gosei Co., Ltd., PAK-01) was placed on an optical substrate 1 formed of borosilicate glass (trade name: BK7, surface roughness RMS=1.22 nm), and a printing pressure was applied to the resin composition 2 by using an extra-flat pressing plate 3 formed of silicon (surface roughness RMS=0.12 nm). Thereafter, light of 365 nm was applied from the optical substrate 1 side to cause a curing reaction, and the extra-flat pressing plate 3 was demolded to form a resin flat surface of the resin composition 2. The surface roughness RMS on the resin flat surface at that time is 0.21 nm, and an extra-flat composite substrate is obtained.

### Embodiment 2

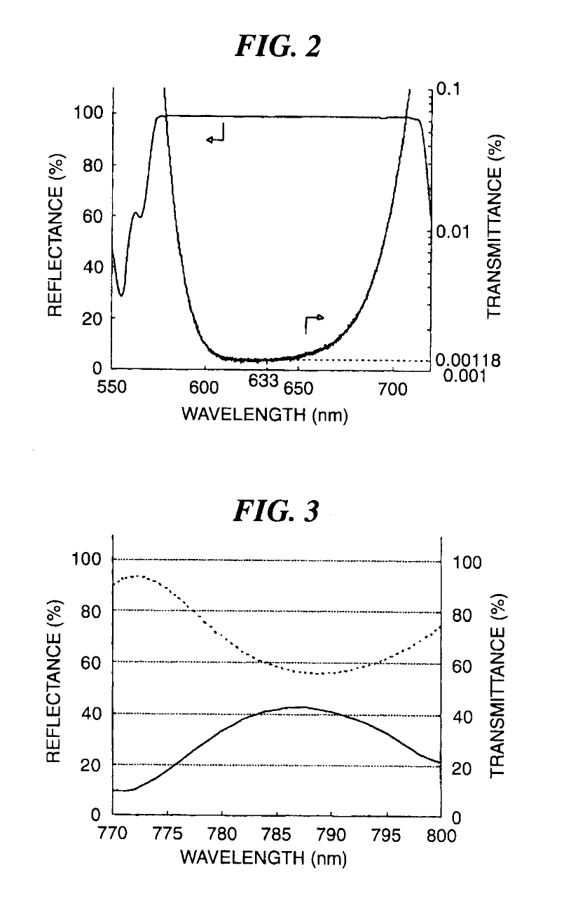

The extra-flat composite substrate obtained in Embodiment 1 is used, and oxide silicon and tantalum oxide each having a ¼ wavelength thickness were alternately stacked by an ion beam sputtering apparatus (from Veeco Instruments Inc.) to stack a dielectric multilayered optical thin film 4 having 41 layers, and, thus, to produce a highly reflection mirror for 633 nm. Consequently, the surface roughness RMS is 0.16 nm, and the results of the reflective spectrum characteristics of FIG. 2 show that the reflectance at the wavelength of 633 nm is a level extremely close to 100%. The transmittance at this time is 0.001% level, and thus it is confirmed that the transmittance is low.

### Comparative Embodiment 1

A highly-polished borosilicate glass substrate (trade name: BK7, surface roughness RMS=0.1 nm) was used, and a dielectric multilayered optical thin film was stacked as in Embodiment 2 to produce a highly reflection mirror for 633 nm. Consequently, the surface roughness RMS is 0.13 nm, and the results of the reflective spectrum characteristics show that the reflectance at the wavelength of 633 nm is a level extremely close to 100%, and the transmittance is 0.001% level.

The above comparison shows that the reflection mirror obtained in the case of the extra-flat composite substrate obtained in Embodiment 1 and the reflection mirror obtained in the case of the highly-polished glass substrate have comparable performances.

### Embodiment 3

The composite substrate obtained in Embodiment 1 was used, and a beam splitter was produced by a similar method to Embodiment 2. Consequently, as shown in FIG. 3, when the wavelength is 787 nm, the transmittance is 57%, and the reflectance is 43%. Thus it is confirmed that the beam splitter has characteristics of a small loss.

### Comparative Embodiment 2

A highly-polished borosilicate glass substrate (trade name: BK7, surface roughness RMS=0.1 nm) was used, and a beam splitter was produced by a similar method to Embodiment 3. Consequently, when the wavelength is 787 nm, the transmittance is 58%, and the reflectance is 43%. Thus it is confirmed that the beam splitter has characteristics of a small loss (the comparative Embodiment 2 terminates).

In the above embodiments, the reflection mirror and the beam splitter are exemplified, however, in a band-pass filter, a band-stop filter, an edge filter, or the like, only each film thickness of multilayer films to be formed is different, and therefore, it is clear that these filters can be produced by similar methods to the above embodiments.

As an optical substrate material used in the composite substrate of the invention, an optical substrate material used in normal optical components can be used in conformity with the desired optical characteristics. For example, there can be used commercially available borosilicate glass, quart, calcium fluoride, magnesium fluoride, barium fluoride, lithium fluoride, silicon, zinc selenide, sapphire, germanium, and so on.

As the resin composition used in the composite substrate, there can be used a resin composition having at least one physical property of a photo-curable property, a thermosetting property, and thermoplasticity. The resin composition preferably has a low viscosity in view of the moldability upon the application of a printing pressure. For these reasons, a diluting solvent can be used in the resin composition in order to reduce the viscosity of the resin composition. However, in this case, the solvent should be volatilized, leading to an effect on the environment, and therefore, it is preferable to reduce the used amount as much as possible. The most preferred is a solventless low viscosity thereof. The optical properties such as the transmittance of a resin can be suitably selected and used in accordance with the desired characteristics of the optical component.

As the photo-curable resin composition, there can be used a commercial photo-curable resin composition such as a resin composition comprising a low-molecular compound, having a vinyl double bond such as an acrylic group and a methacryl group, the oligomer of the low-molecular compound, and a polymeric initiator and a resin composition comprising a low-molecular compound having an epoxy group, the oligomer of the low-molecular compound, and a polymeric initiator. Further, in order to improve the physical properties, an additive such as a thermoplastic resin, a solvent for viscosity reduction, and a reactive diluent can be mixed.

As the thermosetting resin composition, there can be used a commercial thermosetting resin composition such as a phenolic resin composition, an epoxy resin composition, a urea-formaldehyde resin, a melamine resin, a resin composition having a vinyl double bond, a urethane resin composition, a bismaleimide resin composition, a bismaleimide-triazine resin composition, a silicone resin composition, and an inorganic resin composition such as spin-on glass (SOG). Further, in order to improve the physical properties, an additive such as a thermoplastic resin, a solvent for viscosity reduction, and a reactive diluent can be mixed.

As the thermoplastic resin composition, there can be used a commercial resin composition and a solid product such as a film. The commercial resin composition includes polyvinyl chloride, polystyrene, polyethylene, polypropylene, polyester, polycarbonate, polyoxymethylene, polymethylmethacrylate, polyurethane, polysulphone, polyphenylene sulfide, polyether ether ketone, polyamide, polyimide, a silicone resin, and a liquid polymer.

When each resin composition is placed on a substrate, if the resin composition is a solution, an appropriate amount of the solution may be placed on the substrate as it is, but the solution may be applied onto the substrate using a coating applicator. In this case, a suitable application method such as spin coating and dip coating can be used. In the thermosetting resin composition, a film or the like in an unreacted state or in a partially reacted state (a B stage) is placed on a substrate, and thermocompression, curing reaction, and flat formation can be performed. The above-mentioned methods can be also applied to the thermoplastic resin component. However, in that case, since a portion protruded from the shape of a substrate becomes unnecessary to be causative of the loss, it is preferable to use a liquid resin composition that is capable of being reduced to the minimum necessary amount.

For the extra-flat pressing plate for use in the production of a flat surface on a resin, any pressing plate can be used as long as it has an extra-flat surface. In addition to the above substrate materials used in the optical component, ceramic, metal, and so on can be used. Particularly preferred is a semiconductor silicon substrate used as a semiconductor substrate because the semiconductor silicon substrate is versatile in terms of flatness, price and having the size up to 12 inch at present to correspond to the size of the substrate. However, in order to ensure the release characteristics from a resin, it is preferable to apply a release treatment to the surface of the extra-flat pressing plate or a resin surface before application of a printing pressure.

In the curing reaction after the formation of the flat surface, in the case of a photo-curable property, curing may be performed by light irradiation. Upon the light irradiation, the light source may have a wavelength in which the photo-curable property has sensitivity. In this case, when a substrate is transparent, the light irradiation can be performed from the substrate side. When the substrate is opaque and an extra-flat pressing plate is transparent, the light irradiation can be performed from the extra-flat pressing plate side. When both the substrate and the extra-flat pressing plate are opaque, the photo-curable resin cannot be used. In the case of a thermosetting property, a temperature required for curing reaction may be applied to a resin. In the case of thermoplasticity, a temperature required for plastic deformation may be applied to a resin. Thus, the transparencies of a substrate and an extra-flat pressing plate do not matter.

As a method of stacking a functional inorganic optical film for use in the production of an optical component, a large number of evaporation methods have been known. For example, there have been known many methods such as a vacuum evaporation method, a plasma ion assist method, an ion beam assist method, and an ion beam sputter method. Particularly preferred is the ion beam sputter method among the above, and relative to other optical thin film formation methods, it shows the highest denseness and flatness and can realize the stacking at a lower temperature, whereby an optical thin film can be formed with little thermal influence on a resin.

### INDUSTRIAL APPLICABILITY

Regardless the presence of a high level of the polishing of the substrate, an extremely flat resin flat surface is formed on a substrate, and a functional inorganic optical film is stacked on the composite substrate, whereby the production of an optical component can be realized. This constitution can reduce the need for a time based on repeatedly performed polishing treatments required for the production of a conventional polishing of the substrate, expensive devices and the management thereof, and a huge amount of polishing techniques, whereby it is possible to realize highly accurate production on a short time from the production of a substrate to the production of an optical component.

The present invention can also be applied to the case of planarizing the surfaces of an aluminum plate and a quartz glass plate used in a platter of a hard disk drive device which is a storage device.

What is claimed is:

1. A process for producing an optical component using a composite substrate having an extra-flat surface, the process comprising the steps of:
placing a resin composition on an optical substrate;
applying a printing pressure to the resin composition side of the optical substrate with the resin composition by means of an extra-flat pressing plate having a flatter plane than the optical substrate;
curing the resin composition to form a composite substrate; and
stacking a thin film on the composite substrate to form an optical component.

2. The process for producing an optical component according to claim 1 further comprising the steps of:
placing a photo-curable resin composition on an optical substrate;
applying a printing pressure to the resin composition side of the optical substrate with the photo-curable resin composition by means of an extra-flat pressing plate having a flatter plane than the optical substrate;
applying light to the photo-curable resin composition to cure the photo-curable resin composition, and, thus, to form a composite substrate; and
stacking a thin film on the composite substrate to form an optical component,
wherein the resin composition is a photo-curable resin composition.

3. The process for producing an optical component according to claim 1 further comprising the steps of:
placing a thermosetting or thermoplastic resin composition on an optical substrate;
applying a printing pressure to the resin composition side of the optical substrate with the thermosetting or thermoplastic resin composition by means of an extra-flat pressing plate having a flatter plane than the optical substrate;
curing the thermosetting or thermoplastic resin composition by a temperature change to form a composite substrate; and
stacking a thin film on the composite substrate to form an optical component, wherein the resin composition is a thermosetting or thermoplastic resin composition.

4. The process for producing an optical component according to any one of claims 1 to 3, wherein the extra-flat pressing plate having the flat plane is a semiconductor substrate material having a flat plane whose surface roughness is not more than 0.3 nm in terms of a root-mean-square average roughness (RMS), and a resin surface of the composite substrate to be formed has the surface roughness of not more than 0.3 nm in terms of the root-mean-square average roughness (RMS).

5. The process for producing an optical component according to any one of claims 1 to 3, wherein the extra-flat pressing plate having the flat plane is a silicon substrate material having a flat plane whose surface roughness is not more than 0.3 nm in terms of a root-mean-square average roughness (RMS), and a resin surface of the composite substrate to be formed has the surface roughness of not more than 0.3 nm in terms of the root-mean-square average roughness (RMS).

6. The process for producing an optical component according to any one of claims 1 to 3, wherein the extra-flat pressing plate having the flat plane is a highly accurate glass substrate material having a flat plane whose surface roughness is not more than 0.3 nm in terms of a root-mean-square average roughness (RMS), and a resin surface of the composite substrate to be formed has the surface roughness of not more than 0.3 nm in terms of the root-mean-square average roughness (RMS).

7. The process for producing an optical component according to any one of claims 1 to 3, wherein the extra-flat pressing plate having the flat plane is a highly accurate low-thermal expansion glass substrate material having a flat plane whose surface roughness is not more than 0.3 nm in terms of a root-mean-square average roughness (RMS), and the resin surface of the composite substrate to be formed has the surface roughness of not more than 0.3 nm in terms of the root-mean-square average roughness (RMS).

8. The process for producing an optical component according to any one of claims 1 to 3, wherein the thin film is a functional inorganic optical film, and the functional inorganic optical film is stacked to form a reflection mirror.

9. The process for producing an optical component according to any one of claims 1 to 3, wherein the thin film is a functional inorganic optical film, and the functional inorganic optical film is stacked to form a beam splitter.

10. The process for producing an optical component according to any one of claims 1 to 3, wherein the thin film is a functional inorganic optical film, and the functional inorganic optical film is stacked to form a band-pass filter.

11. The process for producing an optical component according to any one of claims 1 to 3, wherein the thin film is a functional inorganic optical film, and the functional inorganic optical film is stacked to form a band-stop filter.

12. The process for producing an optical component according to any one of claims 1 to 3, wherein the thin film is a functional inorganic optical film, and the functional inorganic optical film is stacked to form an edge filter.

13. The process for producing an optical component according to any one of claims 8 to 12, wherein the thin film is a functional inorganic optical film, and the thin film is stacked by low-temperature sputtering.

14. The process for producing an optical component according to any one of claims 8 to 12, wherein the thin film is a functional inorganic optical film, and the thin film is stacked by ion beam sputtering.

15. The process for producing an optical component according to any one of claims 8 to 12, wherein the thin film is a dielectric multilayered optical thin film.

16. The process for producing an optical component according to any one of claims 8 to 12, wherein the thin film is an optical functional metallic film.

17. The process for producing an optical component according to any one of claims 8 to 12, wherein the thin film is a dielectric multilayered optical thin film or an optical functional metallic film, and a lamination by stacking the thin film is a composite film comprising the dielectric multilayered optical thin film and the optical functional metallic film.

18. An optical component being produced by the production process according to any one of claims 1 to 17.
